(19) United States
(12) Patent Application Publication
(10) Pub. No.: US 2022/0123157 A1
(43) Pub. Date: Apr. 21, 2022

(54) METHOD OF MANUFACTURING A S/N RATIO IMPROVED PHOTO-DETECTION DEVICE

(71) Applicant: STANLEY ELECTRIC CO., LTD., Tokyo (JP)

(72) Inventors: Tomoyuki MURATA, Yokohama-shi (JP); Tsutomu OKUBO, Tokyo (JP)

(73) Assignee: STANLEY ELECTRIC CO., LTD., Tokyo (JP)

(21) Appl. No.: 17/564,451

(22) Filed: Dec. 29, 2021

Related U.S. Application Data
(62) Division of application No. 16/192,059, filed on Nov. 15, 2018.

(30) Foreign Application Priority Data
Nov. 16, 2017 (JP) 2017-220847

(51) Int. Cl. H01L 31/0216; H01L 31/18; H01L 31/0232; H01L 31/0203

(52) U.S. Cl. CPC H01L 31/02164; H01L 31/0203; H01L 31/02327; H01L 31/18

(57) ABSTRACT

A method for manufacturing a photo-detection device includes mounting a photo semiconductor element on a substrate; potting first transparent resin on the photo semiconductor element; thermosetting the first transparent resin to form a first resin layer; and potting second transparent resin including optical-shielding fillers on the first resin layer. The second transparent resin slides down from the first resin layer to form a second resin layer to cover a sidewall of the photo semiconductor element and at least a part of a sidewall of the first resin layer. The optical-shielding fillers within the second resin layer drop down due to gravity, and the second resin layer is thermoset after the dropping down, so that the second resin layer is divided into a filler-including resin section including the optical-shielding fillers covering the sidewall of the photo semiconductor element and a filler-excluding resin section excluding the optical-shielding fillers covering at least of the part of the first resin layer.

This application is a Divisional Application of U.S. Application No. 16/192,059, filed Nov. 15, 2018, which claims the priority benefit under 35 U. S. C. § 119 to Japanese Patent Application No. JP2017-220847 filed on Nov. 16, 2017, the disclosures of which are hereby incorporated in their entirety by reference.

### BACKGROUND

### Field

The presently disclosed subject matter relates to a photo-detection device operating as a photosensor and an illuminance sensor, and its manufacturing method.

### Description of the Related Art

FIG. 6A is a cross-sectional view illustrating a first prior art photo-detection device, and FIG. 6B is a plan view of the photo-detection device of FIG. 6A. Note that FIG. 6A is a cross-sectional view taken along the line A-A of FIG. 6B.

In FIGS. 6A and 6B, a photo-detection device 100-1 is constructed by a printed wiring substrate 101 on which a photo semiconductor element 102 such as a photodiode and a phototransistor is mounted. Also, a convex-shaped silicone resin layer 103 serving as a convex lens is formed on the photo semiconductor element 102. Further, an optical-shielding resin layer 104-1 is formed using a transfer molding process to surround the sidewalls of the photo semiconductor element 102 and the convex-shaped silicone resin layer 103. Thus, the photo semiconductor element 102 and the convex-shaped silicone resin layer 103 are sealed by the optical-shielding resin layer 104-1.

In FIGS. 6A and 6B, since the sidewall of the photo semiconductor element 102 is completely covered by the optical-shielding resin layer 104-1, the effect of disturbance light incident from the sidewall of the photo semiconductor element 102 thereinto can be reduced. In this case, the smaller the opening OP10 of the optical-shielding resin layer 104-1, the lower the manufacturing cost of a metal mold used in the transfer molding process.

In the photo-detection device 100-1 of FIGS. 6A and 6B, however, the optical-shielding resin layer 104-1 has to be formed using the transfer molding process to keep off the convex-shaped silicone resin layer 103. For this purpose, a metal mold having an opening corresponding to the protrusion portion of the convex-shaped silicone resin layer 103 provided in the transfer molding process is accurately aligned with the protrusion portion of the convex-shaped silicone resin layer 103, which would require a high precision alignment technique in a mass production process. This would increase the manufacturing cost.

Also, in the photo-detection device 100-1 of FIGS. 6A and 6B, the light taken-in area S10 is the same as the opening OP10 of the convex-shaped silicone resin layer 103, i.e.,

S10=OP10

Since the opening OP10 of the convex-shaped silicone resin layer 103 is relatively small, the light taken-in area S10 is also small. As a result, the light taken-in efficiency of the photo-detection device 100-1 of FIGS. 6A and 6B would be small to reduce the signal-to-noise (S/N) ratio.

FIG. 7A is a cross-sectional view illustrating a second prior art photo-detection device, and FIG. 7B is a plan view of the photo-detection device of FIG. 7A. Note that FIG. 7A is a cross-sectional view taken along the line A-A of FIG. 7B.

In FIGS. 7A and 7B, a photo-detection device 100-2 has an optical-shielding resin layer 104-2 instead of the optical-shielding resin layer 104-1 of the photo-detection device 100-1 of FIGS. 6A and 6B. In this case, the height of the optical-shielding resin layer 104-2 is smaller than that of the optical-shielding resin layer 104-1 of FIGS. 6A and 6B, so that the opening OP20 of the optical-shielding resin layer 104-2 is larger than the opening OP10 of the optical-shielding resin layer 104-1 of FIGS. 6A and 6B. Even in this case, the light taken-in area S20 is the same as the opening OP20 of the convex-shaped silicone resin layer 103, i.e.,

S20=OP20>OP10

Therefore, the light taken-in efficiency of the photo-detection device 100-2 of FIGS. 7A and 7B would be increased as compared with that of the photo-detection device 100-1 of FIGS. 6A and 6B , thus improving the S/N ratio.

Even in the photo-detection device 100-2 of FIGS. 7A and 7B, however, the optical-shielding resin layer 104-2 has to be formed using the transfer molding process to keep off the convex-shaped silicone resin layer 103. For this purpose, a metal mold having an opening corresponding to the protrusion portion of the convex-shaped silicone resin layer 103 provided in the transfer molding process is accurately aligned with the protrusion portion of the convex-shaped silicone resin layer 103, which would require a high precision alignment technique in a mass production process. This would increase the manufacturing cost. Particularly, in the transfer molding process, if the metal mold is deviated from the center of the protrusion portion of the convex-shaped silicone resin layer 103, the convex-shaped silicone resin layer 103 would be crushed. Also, since the opening OP20 of the convex-shaped silicone resin layer 103 is still small, the S/N ratio is still small.

Thus, in the above-described prior art photo-detection devices 100-1 and 100-2 of FIGS. 6A and 6B and FIGS. 7A and 7B, both the improvement of the S/N ratio and the reduction of the manufacturing cost cannot be established.

### SUMMARY

The presently disclosed subject matter seeks to solve one or more of the above-described problems.

According to the presently disclosed subject matter, a photo-detection device includes: a substrate; a photo semiconductor element provided on the substrate; a first resin layer including first transparent resin, provided on the photo semiconductor element; and a second resin layer including second transparent resin, provided on the substrate. The second resin layer is divided into a filler-including resin lower section including optical-shielding fillers, provided on the substrate and surrounding a sidewall of the photo semiconductor element, and a filler-excluding resin upper section excluding the optical-shielding fillers, provided on the filler-including resin lower section and surrounding at least a part of a sidewall of the first resin layer. Therefore, since the first resin layer and the filler-excluding resin upper section above the upper surface of the photo semiconductor element are both transparent, the light taken-in area of the photo-detection device is determined by the light receiving area of the photo semiconductor element or an area larger than it.

Also, a method for manufacturing a photo-detection device includes: mounting a photo semiconductor element on a substrate; potting first transparent resin on the photo semiconductor element; thermosetting the first transparent resin to form a first resin layer; potting second transparent resin including optical-shielding fillers on the first resin layer, the second transparent resin sliding down from the first resin layer to form a second resin layer to cover a sidewall of the photo semiconductor element and at least a part of a sidewall of the first resin layer; the optical-shielding fillers within the second resin layer dropping down due to gravity; thermosetting the second resin layer after the dropping, so that the second resin layer is divided into a filler-including resin section including the optical-shielding fillers covering the sidewall of the photo semiconductor element and a filler-excluding resin section excluding the optical-shielding fillers covering at least part of the first resin layer.

Thus, according to the presently disclosed subject matter, since the light taken-in area of the photo-detection device is determined by the light receiving area of the photo semiconductor element or an area larger than it, the light taken-in area of the photo-detection device can be increased, thus improving the S/N ratio. Also, since no metal mold is required in the manufacturing method, the manufacturing cost can be reduced.

### BRIEF DESCRIPTION OF THE DRAWINGS

The above and other advantages and features of the presently disclosed subject matter will be more apparent from the following description of certain embodiments, taken in conjunction with the accompanying drawings, as compared with the prior art, wherein:

FIG. 1A is a cross-sectional view illustrating a first embodiment of the photo-detection device according to the presently disclosed subject matter;

FIG. 1B is a plan view of the photo-detection device of FIG. 1A;

FIGS. 2A through 2E are cross-sectional views for explaining a method for manufacturing the photo-detection device of FIGS. 1A and 1B;

FIGS. 3A and 3B are cross-sectional views illustrating first and second modifications, respectively, of the photo-detection device of FIG. 1A;

FIG. 4A is a cross-sectional view illustrating a second embodiment of the photo-detection device according to the presently disclosed subject matter;

FIG. 4B is a plan view of the photo-detection device of FIG. 4A;

FIGS. 5A and 5B are cross-sectional views illustrating first and second modifications, respectively, of the photo-detection device of FIG. 4A;

FIG. 6A is a cross-sectional view illustrating a first prior art photo-detection device;

FIG. 6B is a plan view of the photo-detection device of FIG. 6A;

FIG. 7A is a cross-sectional view illustrating a second prior art photo-detection device; and

FIG. 7B is a plan view of the photo-detection device of FIG. 7A.

### DETAILED DESCRIPTION OF EXEMPLARY EMBODIMENTS

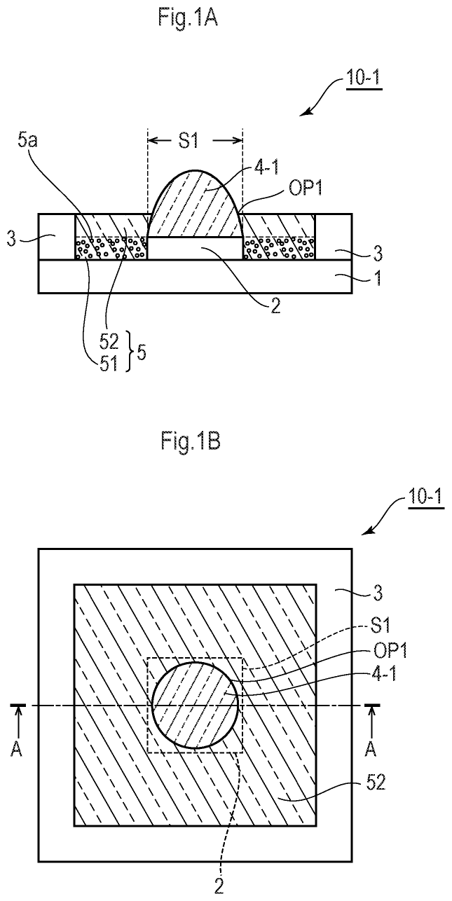

FIG. 1A is a cross-sectional view illustrating a first embodiment of the photo-detection device according to the presently disclosed invention, and FIG. 1B is a plan view of the photo-detection device of FIG. 1A. Note that FIG. 1A is a cross-sectional view taken along the line A-A of FIG. 1B.

In FIGS. 1A and 1B, a photo-detection device 10-1 is constructed by a printed wiring substrate 1 on which an about 100 to 200 μm thick photo semiconductor element 2 such as a photodiode and a phototransistor is mounted. Also, a rectangular frame 3 made of ceramic is formed on a periphery of an upper surface of the printed wiring substrate 1. Further, a convex-shaped resin layer 4-1 serving as a convex lens is formed on the photo semiconductor element 2. The convex-shaped resin layer 4-1 is made of thermosetting transparent resin such as silicone resin. In this case, the height of the frame 3 is larger than that of the photo semiconductor element 2 and is smaller than a total height of the photo semiconductor element 2 and the convex-shaped resin layer 4-1. Furthermore, a resin layer 5 is formed on the printed wiring substrate 1 between the frame 3 and each of the photo semiconductor element 2 and the convex-shaped resin layer 4-1.

The resin layer 5 has substantially the same height as that of the frame 3, and includes thermosetting transparent resin such as silicone resin. The resin layer 5 is constructed by a filler-including resin lower section 51 and a filler-excluding resin upper section 52. In this case, the filler-including resin lower section 51 includes about 10 to 50 μm diameter reflective fillers 5a made of TiO₂, Al₂O₃ and so on to exhibit a reflective or optical-shielding characteristic, while the filler-excluding resin upper section 52 includes no reflective fillers to exhibit a transparent characteristic.

The filler-including resin lower section 51 surrounds the sidewall of the photo semiconductor element 2. Therefore, disturbance light incident from the sidewall of the photo semiconductor element 2 thereinto can be reduced.

On the other hand, the filler-excluding resin upper section 52 surrounds a part of the sidewall of the convex-shaped resin layer 4-1. Therefore, only the convex-shaped resin layer 4-1 and the filler-excluding resin upper section 52, which are both transparent, are present above the upper surface of the photo semiconductor element 2. As a result, the light taken-in area S1 of the photo-detection device 10-1 is determined by the light receiving area of the photo semiconductor element 2 which is larger than the opening OP1 of the resin layer 5. In other words, the light taken-in area S1 is about the same as the area of the photo semiconductor element 2, although the light taken-in area S1 is actually a little smaller than the area of the photo semiconductor element 2. Thus, the light taken-in area S1 is larger than the opening OP1 of the resin layer 5, i.e.,

S1>OP1

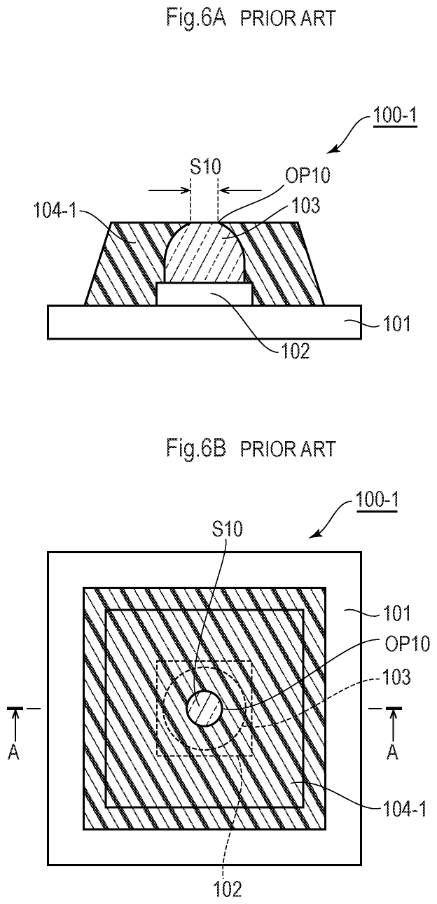

:.S1>OP10 (FIGS. 6A and 6B)

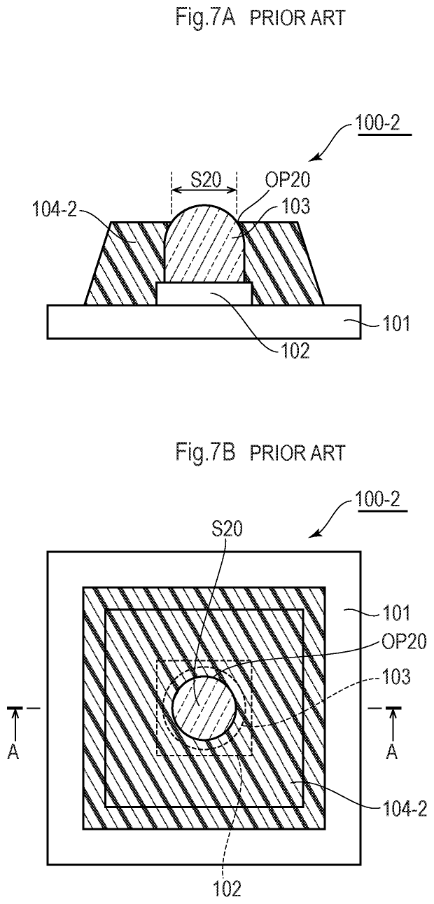

S1>OP20 (FIGS. 7A and 7B)

The S/N ratio of the photo-detection device 10-1 of FIGS. 1A and 1B can be improved as compared with the photo-detection devices 100-1 and 100-2 of FIGS. 6A and 6B and FIGS. 7A and 7B.

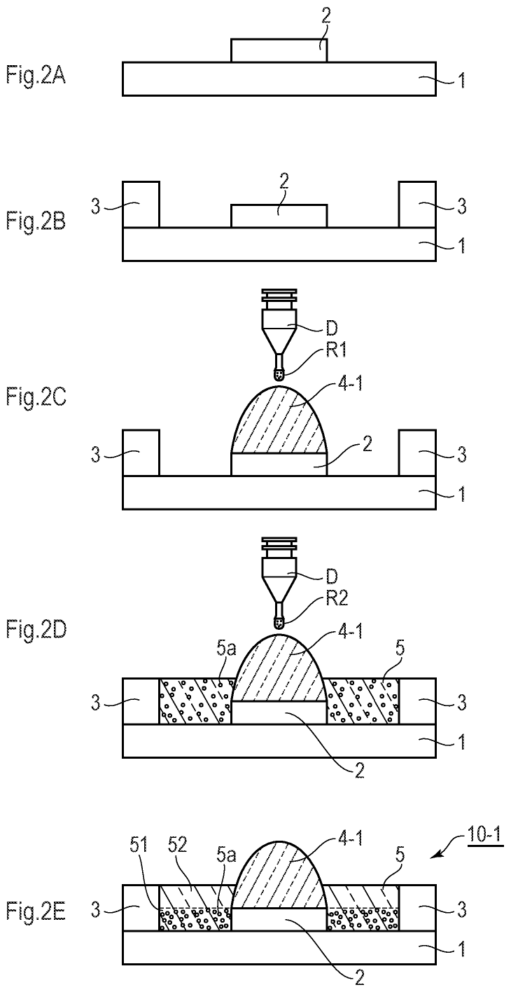

A method for manufacturing the photo-detection device 10-1 of FIGS. 1A and 1B will now be explained with reference to FIGS. 2A through 2E.

First, referring to a photo semiconductor element mounting step illustrated in FIG. 2A, a photo semiconductor element 2 is mounted on a printed wiring pattern of a printed wiring substrate 1.

Next, referring to a frame adhering step illustrated in FIG. 2B, a rectangular frame 3 is adhered by adhesives onto a periphery of the upper surface of the printed wiring substrate 1. Note that the frame adhering step of FIG. 2B can be carried out before the photo semiconductor mounting step of FIG. 2A.

Next, referring to a silicone resin potting and thermally-setting step illustrated in FIG. 2C, a nozzle of a dispenser D is placed above the center of the photo semiconductor element 2. Then, silicone resin R1 is potted on the photo semiconductor element 2. In this case, the silicone resin R1 on the photo semiconductor element 2 becomes convex due to the surface tension phenomenon. Then, the device is annealed at a high temperature such as about 150° C. for about 1 hour to thermally set the silicone resin R1 to form a convex-shaped resin layer 4-1 on the photo semiconductor element 2.

Next, referring to a reflective filler including silicone resin potting step as illustrated in FIG. 2D, the nozzle of the dispenser D is placed above the center of the convex-shaped resin layer 4-1. Then, reflective-filler including silicone resin R2 of silicone resin is potted on the convex-shaped resin layer 4-1. Therefore, the reflective-filler including silicone resin R2 slides down on the surface of the convex-shaped resin layer 4-1 due to gravity, so that a resin layer 5 is filled between the frame 3 and each of the photo semiconductor element 2 and the convex-shaped resin layer 4-1. Note the amount of the reflective fillers 5a in the reflective-filler including silicone resin R2 is adjusted in advance, so that the height of a filler including resin lower section 51, which will be later formed, coincides with the height of the photo semiconductor element 2. Also, in order to easily slide down the reflective-filler including silicone resin R2 on the convex-shaped resin layer 4-1, it is preferable that the top portion of the convex-shaped resin layer 4-1 is sharper.

Finally, referring to a reflective filler falling and thermosetting process as illustrated in FIG. 2E, the device is annealed at a low temperature such as about 60 to 100° C. for several hours, so that the reflective fillers 5a fall down within the reflective-filler including silicone resin R2 due to the gravity. As a result, the resin layer 5 is divided into a filler-including resin lower section 51 including the reflective fillers 5a and a filler-excluding resin upper section 52 excluding the reflective fillers 5a. After that, the device is annealed at a high temperature such as 150° C. for about one hour, to thermoset the filler-including resin lower section 51 and the filler-excluding resin upper section 52. Thus, the photo-detection device 10-1 of FIGS. 1A and 1B is completed.

According to the manufacturing method as illustrated in FIGS. 2A through 2E, since no metal mold is required, the manufacturing cost can be reduced.

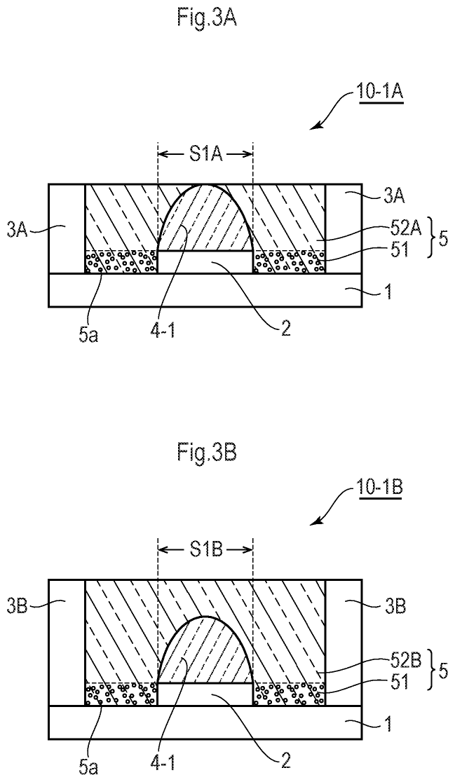

In FIG. 3A, which illustrates a first modification of the photo-detection device 10-1 of FIG. 1A, a photo-detection device 10-1A includes a frame 3A instead of the frame 3 of FIG. 1A, and also, includes a filler-excluding resin upper section 52A instead of the filler-excluding resin upper section 52 of FIG. 1A. In FIG. 3A, the height of the frame 3A is about the same as a total height of the photo semiconductor element 2 and the convex-shaped resin layer 4-1. A method for manufacturing the photo-detection device 10-1A is about the same as the method as illustrated in FIGS. 2A through 2E except that the potting amount of the reflective-filler including silicone resin R2 of FIG. 2D is slightly increased. Also, the amount of the reflective fillers 5a of the reflective-filler including silicone resin R2 is adjusted, so that the thickness of the filler-including resin lower section 51 is made close to that of the photo semiconductor element 2.

In FIG. 3A, since the filler-including resin lower section 51, which is reflective, covers the sidewall of the photo semiconductor element 2, the effect of disturbance light incident from the sidewall of the photo semiconductor element 2 thereinto can be reduced. Also, since the filler-excluding resin upper section 52A, which is transparent, completely covers the sidewall of the convex-shaped resin layer 4-1, the convex-shaped resin layer 4-1 and the filler-excluding resin upper section 52A, which are both transparent, are placed above the photo semiconductor element 2, so that the light taken-in area S1A is about the same as the area S1 of the photo semiconductor element 2, i.e.,

S1A=S1.

Thus, the S/N ratio can be increased in the same way as in the photo-detection device 10-1 of FIG. 1A.

In FIG. 3B, which illustrates a second modification of the photo-detection device 10-1 of FIG. 1A, a photo-detection device 10-1B includes a frame 3B instead of the frame 3 of FIG. 1A, and also, includes a filler-excluding resin upper section 52B instead of the filler-excluding resin upper section 52 of FIG. 1A. In FIG. 3B, the height of the frame 3B is larger than a total height of the photo semiconductor element 2 and the convex-shaped resin layer 4-1. A method for manufacturing the photo-detection device 10-1B is about the same as the method as illustrated in FIGS. 2A through 2E except that the potting amount of the reflective-filler including silicone resin R2 of FIG. 2D is further increased. Also, the amount of the reflective fillers 5a of the reflective-filler including silicone resin R2 is adjusted, so that the thickness of the filler-including resin lower section 51 is made close to that of the photo semiconductor element 2.

Even in FIG. 3B, since the filler-including resin lower section 51, which is reflective, covers the sidewall of the photo semiconductor element 2, the effect of disturbance light incident from the sidewall of the photo semiconductor element 2 thereinto can be reduced. Also, since the filler-excluding resin upper section 52B, which is transparent, completely covers the sidewall of the convex-shaped resin layer 4-1, the convex-shaped resin layer 4-1 and the filler-excluding resin upper section 52B, which are both transparent, are placed above the photo semiconductor element 2, so that the light taken-in area S1B is about the same as the area S1 of the photo semiconductor element 2, i.e.,

S1B=S1.

The S/N ratio can be increased in the same way as in the photo-detection device 10-1 of FIG. 1A.

Thus, in the photo-detection devices 10-1, 10-1A and 10-1B of FIGS. 1A, 3A and 3B, regardless of the thickness of the filler-excluding resin upper sections 52, 52A and 52B, the light taken-in areas S1, S1A and S1B are determined by the photo semiconductor element 2, so that the S/N ratio can be improved.

In FIGS. 1A, 3A and 3B, when the convex-shaped resin layer 4-1 is expected to be operated as a convex lens, the components of silicone resin of the convex-shaped resin layer 4-1 are made different from those of silicone resin of the resin layer 5, so that the refractive index of the convex-shaped resin layer 4-1 is larger than that of the resin layer 5.

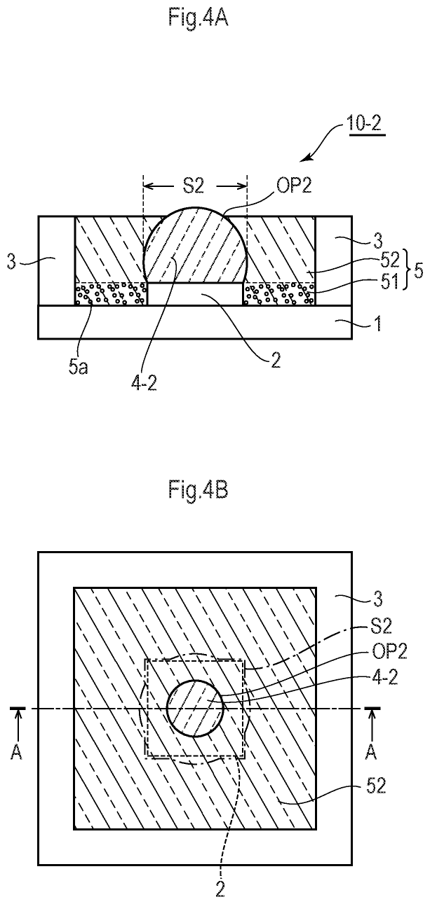

FIG. 4A is a cross-sectional view illustrating a second embodiment of the photo-detection device according to the presently disclosed invention, and FIG. 4B is a plan view of the photo-detection device of FIG. 4A. Note that FIG. 4A is a cross-sectional view taken along the line A-A of FIG. 4B.

In FIGS. 4A and 4B, the photo-detection device 10-2 is constructed by a spherical-shaped resin layer 4-2 made of transparent resin instead of the convex-shaped resin layer 4-1 of the photo-detection device 10-1 of FIGS. 1A and 1B. The filler-including resin lower section 51 surrounds the sidewall of the photo semiconductor element 2. Therefore, disturbance light incident from the sidewall of the photo semiconductor element 2 thereinto can be reduced.

On the other hand, the filler-excluding resin upper section 52 surrounds a part of the sidewall of the spherical-shaped resin layer 4-2. Therefore, only the spherical-shaped resin layer 4-2 and the filler-excluding resin upper section 52, which are both transparent, are present above the upper surface of the photo semiconductor element 2. In this case, the spherical-shaped resin layer 4-2 is protruded from the photo semiconductor element 2 viewed from the top. Also, the spherical-shaped resin layer 4-2 serves as a convex lens. Therefore, the light taken-in area of the protruded portions of the spherical-shaped resin layer 4-2 contributes to the light taken-in area S2 of the photo-detection device 10-2. As a result, the light taken-in area S2 of the photo-detection device 10-2 is determined by a larger area than the light receiving area of the photo semiconductor element 2 which is larger than the opening OP2 of the resin layer 5. Thus, the light taken-in area S2 is larger than the light taken-in area S1 of the photo-detection device 10-1 of FIGS. 1A and 1B, i.e.,

S2>OP2

S2>S1

The S/N ratio of the photo-detection device 10-2 of FIGS. 4A and 4B can be improved as compared with the photo-detection device 10-1 of FIGS. 1A and 1B. A method for manufacturing the photo-detection device 10-2A is about the same as the method as illustrated in FIGS. 2A through 2E except that the potting amount of the silicone resin R1 of FIG. 2C is slightly increased. In this case, the silicone resin R1 becomes spherical due to the surface tension. Also, the parts of the spherical resin R1 are protruded from the photo semiconductor element 2 viewed from the top. After that, the device is annealed at a high temperature such as 150° C. for about one hour to thermoset the silicone resin R1. Thus, the spherical-shaped resin layer 4-2 is formed.

Even in the manufacturing method of the photo-detection device 10-2 of FIGS. 4A and 4B, since no metal mold is required, the manufacturing cost can be reduced.

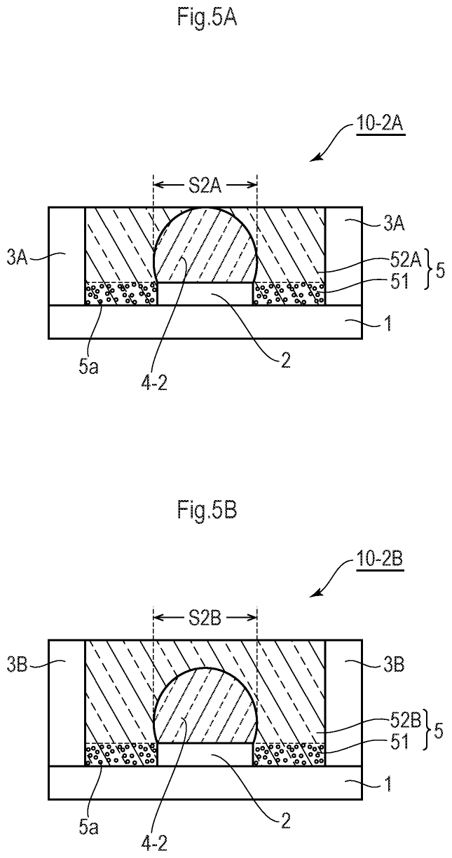

In FIG. 5A, which illustrates a first modification of the photo-detection device 10-2 of FIG. 4A, a photo-detection device 10-2A includes a frame 3A instead of the frame 3 of FIG. 1A, and also, includes a filler-excluding resin upper section 52A instead of the filler-excluding resin upper section 52 of FIG. 4A. In FIG. 3A, the height of the frame 3A is about the same as a total height of the photo semiconductor element 2 and the spherical-shaped resin layer 4-2. A method for manufacturing the photo-detection device 10-2A is about the same as the method as illustrated in FIGS. 2A through 2E except that the potting amount of the reflective-filler including silicone resin R2 of FIG. 2D is slightly increased. Also, the amount of the reflective fillers 5a of the reflective-filler including silicone resin R2 is adjusted, so that the thickness of the filler-including resin lower section 51 is made close to that of the photo semiconductor element 2.

In FIG. 5A, since the filler-including resin lower section 51, which is reflective, covers the sidewall of the photo semiconductor element 2, the effect of disturbance light incident from the sidewall of the photo semiconductor element 2 thereinto can be reduced. Also, since the filler-excluding resin upper section 52A, which is transparent, completely covers the sidewall of the spherical-shaped resin layer 4-2, the spherical-shaped resin layer 4-2 and the filler-excluding resin upper section 52A, which are both transparent, are placed above the photo semiconductor element 2, so that the light taken-in area S2A is larger than the area of the photo semiconductor element 2, i.e.,

S2A=S2

Thus, the S/N ratio can be increased in the same way as in the photo-detection device 10-2 of FIG. 4A.

In FIG. 5B, which illustrates a second modification of the photo-detection device 10-2 of FIG. 4A, a photo-detection device 10-2B includes a frame 3B instead of the frame 3 of FIG. 4A, and also, includes a filler-excluding resin upper section 52B instead of the filler-excluding resin upper section 52 of FIG. 4A. In FIG. 5B, the height of the frame 3B is larger than a total height of the photo semiconductor element 2 and the spherical-shaped resin layer 4-2. A method for manufacturing the photo-detection device 10-2B is about the same as the method as illustrated in FIGS. 2A through 2E except that the potting amount of the reflective-filler including silicone resin R2 of FIG. 2D is further increased. Also, the amount of the reflective fillers 5a of the reflective-filler including silicone resin R2 is adjusted, so that the thickness of the filler-including resin lower section 51 is made close to that of the photo semiconductor element 2.

Even in FIG. 5B, since the filler-including resin lower section 51, which is reflective, covers the sidewall of the photo semiconductor element 2, the effect of disturbance light incident from the sidewall of the photo semiconductor element 2 thereinto can be reduced. Also, since the filler-excluding resin upper section 52B, which is transparent, completely covers the sidewall of the spherical-shaped resin layer 4-2, the spherical-shaped resin layer 4-2 and the filler-excluding resin upper section 52B, which are both transparent, are placed above the photo semiconductor element 2, so that the light taken-in area S2B is larger than the area of the photo semiconductor element 2, i.e.,

S2B=S2

The S/N ratio can be increased in the same way as in the photo-detection device 10-2 of FIG. 4A.

Thus, in the photo-detection device 10-2, 10-2A and 10-2B of FIGS. 4A, 5A and 5B, regardless of the thickness of the filler-excluding resin upper sections 52, 52A and 52B, the light taken-in areas S2, S2A and S2B are determined by a larger area than the photo semiconductor element 2, so that the S/N ratio can be improved.

In FIGS. 4A, 5A and 5B, when the spherical-shaped resin layer 4-2 is expected to be operated as a convex lens, the components of silicone resin of the spherical-shaped resin layer 4-2 are made different from those of silicone resin of the resin layer 5, so that the refractive index of the spherical-shaped resin layer 4-2 is larger than that of the resin layer 5.

In the above-described embodiments, the frame 3 is provided on the printed wiring substrate 1. However, a congregated printed wiring substrate can be provided instead of multiple printed wiring substrates 1. In this case, multiple photo semiconductor are mounted on the congregated wiring substrate, and a frame is provided on a periphery of a surface of the congregated wiring substrate. Then, first transparent resin is potted and thermoset, and after that, second transparent resin including reflective-fillers is potted and thermoset. Finally, the congregated wiring substrate is cut by blades into individual photo-detection devices.

Also, in the above-described embodiments, the reflective fillers 5a can be replaced by light absorbing fillers made of carbon black whose periphery is fixed by core material. The reflective fillers 5a and the light absorbing fillers exhibit an optical shielding characteristic.

Further, in the above-described embodiments, other substrates than the printed wiring substrate 1 can be used.

It will be apparent to those skilled in the art that various modifications and variations can be made in the presently disclosed subject matter without departing from the spirit or scope of the presently disclosed subject matter. Thus, it is intended that the presently disclosed subject matter covers the modifications and variations of the presently disclosed subject matter provided they come within the scope of the appended claims and their equivalents. All related or prior art references described above and in the Background section of the present specification are hereby incorporated in their entirety by reference.

1. A method for manufacturing a photo-detection device comprising:
mounting a photo semiconductor element on a substrate;
potting first transparent resin on said photo semiconductor element;
thermosetting said first transparent resin to form a first resin layer;
potting second transparent resin including optical-shielding fillers on said first resin layer, said second transparent resin sliding down from said first resin layer to form a second resin layer to cover a sidewall of said photo semiconductor element and at least a part of a sidewall of said first resin layer;
said optical-shielding fillers within said second resin layer dropping down due to gravity;
thermosetting said second resin layer after said dropping down, so that said second resin layer is divided into a filler-including resin section including said optical-shielding fillers covering said sidewall of said photo semiconductor element and a filler-excluding resin section excluding said optical-shielding fillers covering said at least of the part of said first resin layer.

2. The method as set forth in claim 1, further comprising:
adhering a frame on a periphery of an upper surface of said substrate before said potting said first transparent resin.

3. The method as set forth in claim 1, wherein said first resin layer is convex-shaped.

4. The method as set forth in claim 1, wherein said first resin layer is spherical-shaped.

5. The method as set forth in claim 3, wherein a part of said first resin layer is protruded from said photo semiconductor element viewed from the top.

6. The method as set forth in claim 1, wherein said optical-shielding fillers are reflective fillers.

7. The method as set forth in claim 1, wherein said optical-shielding fillers are light-absorbing fillers.

8. The device as set forth in claim 1, wherein a refractive index of said first transparent resin is larger than a refractive index of said second transparent resin.
